(19) United States
(12) Patent Application Publication
(10) Pub. No.: US 2019/0345608 A1
(43) Pub. Date: Nov. 14, 2019

(54) METHOD OF PROVIDING A PLASMA ATOMIC LAYER DEPOSITION

(71) Applicant: Lam Research Corporation, Fremont, CA (US)

(72) Inventors: Pulkit AGARWAL, Beaverton, OR (US); Purushottam KUMAR, Hillsboro, OR (US); Adrien LAVOIE, Newberg, OR (US)

(21) Appl. No.: 15/974,500

(22) Filed: May 8, 2018

(51) Int. Cl. C23C 16/455; H01J 37/32; H01L 21/02; C23C 16/40; C23C 16/52

(52) U.S. Cl. CPC C23C 16/45536; H01J 37/32174; H01L 21/0228; C23C 16/45553; H01L 21/02164; C23C 16/401; C23C 16/52; H01L 21/02274

(57) ABSTRACT

A method for depositing a layer on a substrate is provided. A plurality of plasma atomic layer deposition (ALD) layers is deposited over the substrate, wherein each plasma ALD layer of the plurality of ALD layers is deposited at a first RF power. The plurality of plasma ALD layers is densified, comprising generating a densifying plasma using a second RF power greater than the first RF power, wherein at least one of the plurality of plasma ALD layers is densified.

### BACKGROUND

The present disclosure relates to the formation of semiconductor devices. More specifically, the disclosure relates to the formation of semiconductor devices where a layer is deposited by plasma atomic layer deposition. Plasma atomic layer deposition provides a plurality of cycles, where each cycle deposits a thin layer.

### SUMMARY

To achieve the foregoing and in accordance with the purpose of the present disclosure, a method for depositing a layer on a substrate is provided. A plurality of plasma atomic layer deposition (ALD) layers is deposited over the substrate, wherein each plasma ALD layer of the plurality of ALD layers is deposited at a first RF power. The plurality of plasma ALD layers is densified, comprising generating a densifying plasma using a second RF power greater than the first RF power, wherein at least one of the plurality of plasma ALD layers is densified.

These and other features of the present disclosure will be described in more detail below in the detailed description of the disclosure and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a high level flow chart of an embodiment.

FIG. 2 is a schematic view of a process chamber that may be used in an embodiment.

FIG. 3 is a schematic view of a computer system that may be used in practicing an embodiment.

FIG. 4 is schematic cross-sectional views of a stack processed according to an embodiment.

FIGS. 5A-C are schematic cross-sectional views of another stack processed according to an embodiment.

FIG. 6 is more detailed flow chart of an ALD process.

FIG. 7 is a more detailed flow chart of a densifying process.

FIG. 8 is a more detailed flow chart of another ALD process.

FIG. 9 is a bar graph of regular ALD, 10 cycles of soft ALD, 20 cycles of soft ALD, and 30 cycles of soft ALD, versus thickness of silicon oxide in angstroms.

### DETAILED DESCRIPTION

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well known process steps and/or structures have not been described in detail in order to not unnecessarily obscure the present disclosure.

Oxide (silicon oxide (SiO₂)) film quality is very important in certain applications because it directly affects device performance and yield. Especially as the device size is shrinking, the development of sub-nm oxide film with high density/quality has become very important. In the conventional process, good quality is achieved by high RF power conversion plasma. However, high radio frequency (RF) power conversion plasma can easily damage the underlying substrate resulting in poor device performance and yield.

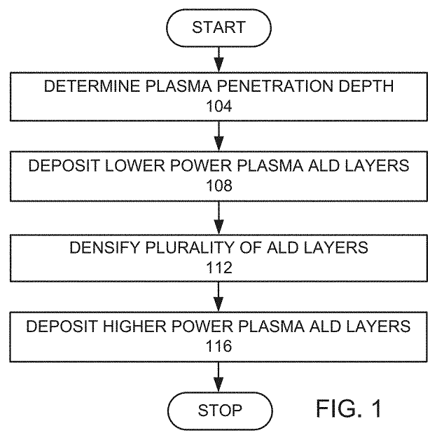

To facilitate understanding, FIG. 1 is a high level flow chart of an embodiment. Plasma penetration depth of a plasma ALD deposition at a regular RF power is determined (step 104). A plurality of plasma ALD layers are deposited with a first RF power that is lower than the regular RF power. (step 108) The plurality of ALD layers is densified by generating a densifying plasma using a second RF power that is greater than the first RF power, wherein all of the plurality of ALD layer is densified (step 112). A plurality of plasma ALD layers are deposited with a third RF power that is higher than the first RF power (step 116).

### Example

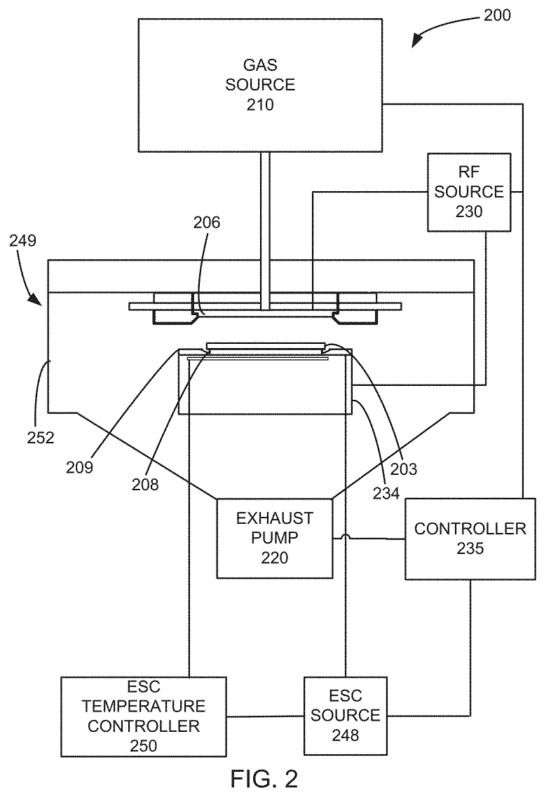

FIG. 2 is a schematic view of a process chamber which may be used in an embodiment. In one or more embodiments, a process chamber 200 comprises a gas distribution plate 206 providing a gas inlet and an electrostatic chuck (ESC) 208, within a chamber 249, enclosed by a chamber wall 252. Within the chamber 249, a wafer 203 is positioned over the ESC 208, which is a substrate support. An edge ring 209 surrounds the ESC 208. An ESC source 248 may provide a bias to the ESC 208. A gas source 210 is connected to the chamber 249 through the gas distribution plate 206. An ESC temperature controller 250 is connected the ESC 208. A radio frequency (RF) source 230 provides RF power to a lower electrode and/or an upper electrode, which in this embodiment are the ESC 208 and the gas distribution plate 206. In an exemplary embodiment, 400 kHz (kilohertz), 60 MHz (megahertz), and optionally 2 MHz, 27 MHz power sources make up the RF source 230 and the ESC source 248. In this embodiment, the upper electrode is grounded. In this embodiment, one generator is provided for each frequency. In other embodiments, the generators may be in separate RF sources, or separate RF generators may be connected to different electrodes. For example, the upper electrode may have inner and outer electrodes connected to different RF sources. Other arrangements of RF sources and electrodes may be used in other embodiments. A controller 235 is controllably connected to the RF source 230, the ESC source 248, an exhaust pump 220, and the gas source 210. An example of such a chamber is the Striker™ Oxide system manufactured by Lam Research Corporation of Fremont, Calif.

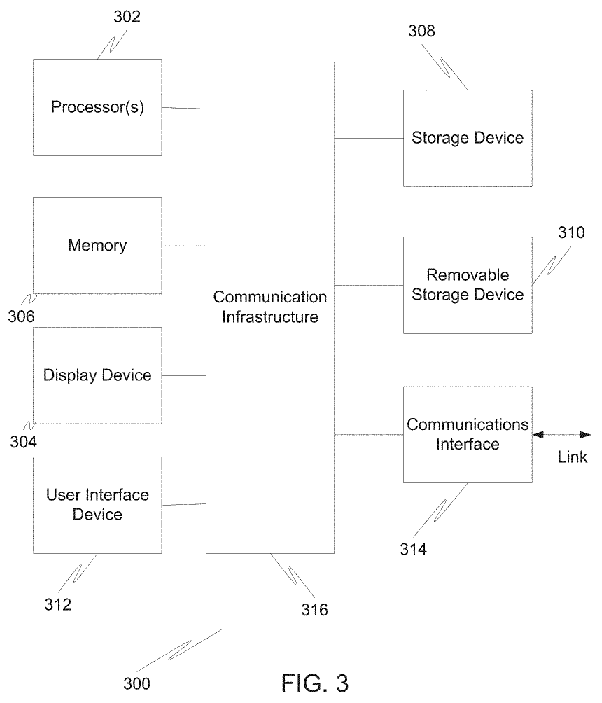

FIG. 3 is a high level block diagram showing a computer system 300, which is suitable for implementing a controller 235 used in embodiments. The computer system may have many physical forms ranging from an integrated circuit, a printed circuit board, and a small handheld device up to a huge super computer. The computer system 300 includes one or more processors 302, and further can include an electronic display device 304 (for displaying graphics, text, and other data), a main memory 306 (e.g., random access memory (RAM)), storage device 308 (e.g., hard disk drive), removable storage device 310 (e.g., optical disk drive), user interface devices 312 (e.g., keyboards, touch screens, keypads, mice or other pointing devices, etc.), and a communication interface 314 (e.g., wireless network interface). The communication interface 314 allows software and data to be transferred between the computer system 300 and external devices via a link. The system may also include a communications infrastructure 316 (e.g., a communications bus, cross-over bar, or network) to which the aforementioned devices/modules are connected.

Information transferred via communications interface 314 may be in the form of signals such as electronic, electromagnetic, optical, or other signals capable of being received by communications interface 314, via a communication link that carries signals and may be implemented using wire or cable, fiber optics, a phone line, a cellular phone link, a radio frequency link, and/or other communication channels. With such a communications interface, it is contemplated that the one or more processors 302 might receive information from a network, or might output information to the network in the course of performing the above-described method steps. Furthermore, method embodiments may execute solely upon the processors or may execute over a network such as the Internet, in conjunction with remote processors that shares a portion of the processing.

The term “non-transient computer readable medium” is used generally to refer to media such as main memory, secondary memory, removable storage, and storage devices, such as hard disks, flash memory, disk drive memory, CD-ROM, and other forms of persistent memory and shall not be construed to cover transitory subject matter, such as carrier waves or signals. Examples of computer code include machine code, such as produced by a compiler, and files containing higher level code that are executed by a computer using an interpreter. Computer readable media may also be computer code transmitted by a computer data signal embodied in a carrier wave and representing a sequence of instructions that are executable by a processor.

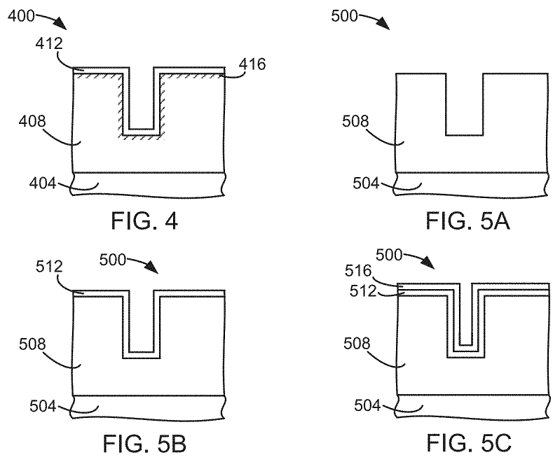

In an example of an implementation of the embodiment, plasma penetration depth of a plasma ALD deposition at a regular RF power is determined (step 104). FIG. 4 is a cross sectional view of part of a stack 400 with a wafer 404 disposed below an intermediate layer 408, disposed below plurality of high quality silicon oxide layers 412 deposited by plasma ALD. During the plasma ALD deposition, an oxygen containing plasma is formed in order to transform a silicon containing precursor into silicon oxide. An RF power is provided to provide the oxygen containing plasma. The RF power is optimized to so that the plurality silicon oxide layers 412 is of high quality. It is found that the oxygen containing plasma causes damage to the intermediate layer 408. In this example, the thickness of the damage is measured to be about 20 \acute{Å}. An example of a process for determining the depth of penetration will be described after the remaining process is described in detail, since the process for determining the depth of penetration is dependent upon the method used for the deposition of ALD layers at a first RF power that is lower than the regular RF power.

A new substrate with an intermediate layer is placed in the plasma processing chamber. FIG. 5A is a cross sectional view of part of a stack 500 with a wafer 504 disposed below an intermediate layer 508. In this example, the intermediate layer 508 is silicon nitride. In other embodiments, the intermediate layer 508 may be of another material, such as polysilicon, silicon oxynitride (SiON), carbon hardmask, photoresist or a metal containing layer, such as a germanium-antimony-tellurium (GST) layer.

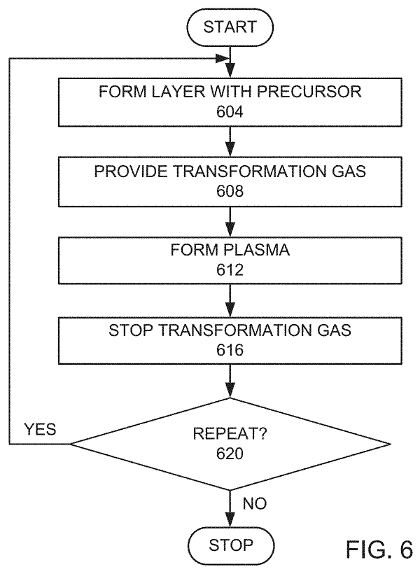

A plurality of plasma ALD layers is deposited with a first RF power that is lower than the regular RF power (step 108), which produces soft ALD silicon oxide layers. FIG. 6 is a more detailed flow chart of providing the plurality of plasma ALD layers with a first RF power (step 108). A layer of precursor is formed (step 604). In this example, for depositing silicon oxide, a silicon containing precursor of a silane is provided, such as bis(diethylamino)silane (BDEAS), bis(tert-butylamino)silane (BTBAS), diisopropylamino silane (DIPAS), tris(dimethylamino)silane (TDMAS) or other silanes. In this example, the silane forms a monolayer on a surface of the intermediate layer 508. In this example, the flow of the silicon containing precursor into the plasma processing chamber is stopped and a transformation gas is provided by flowing the oxygen containing gas into the plasma processing chamber (step 608). In this example, a transformation gas comprises at least one of oxidizer and inters such as at least one of nitrous oxide (N₂O), helium (He), oxygen (O₂) and argon (Ar). The transformation gas is transformed into a plasma (step 612). In this example, a lower RF power is used to transform the transformation gas into a plasma. In this example, the RF power provided is in the range of 500 to 1000 watts applied through the gas distribution plate 206. A bias RF power in the range of 500 to 1000 watts may also be applied through the ESC 208. The plasma from the transformation gas reacts with the silicon containing precursor to transform the silicon containing precursor into a silicon oxide layer. After between 0.1 to 1 seconds, the flow of the transformation gas is stopped (step 616). The cycle is repeated (step 620) until a silicon oxide deposition with a thickness of about 20 \acute{Å} is deposited, since it was determined that the thickness of the damage was about 20 \acute{Å}, and therefore plasma at the power provided by the densification penetrates about 20 \acute{Å}.

FIG. 5B is a cross sectional view of part of the stack after the plurality of plasma ALD layers 512 has been deposited. Because the deposition process has a lower RF power than RF power used to deposit the high quality silicon oxide layer, the intermediate layer is not damaged. The RF power is optimized to minimize damage to the intermediate layer. As a result, the deposited silicon oxide is a lower quality (i.e. lower density), since the RF power is optimized to minimize damage instead of being optimized to provide the highest quality silicon oxide deposition. Such a lower quality silicon oxide deposition may reduce the performance of semiconductor devices manufactured from such silicon oxide depositions.

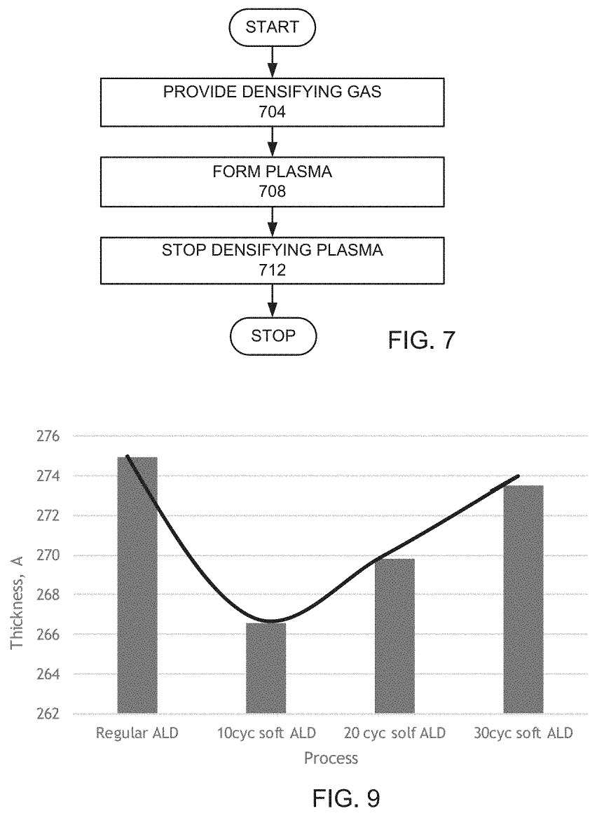

The plurality of ALD layers is densified by generating a densifying plasma using a second RF power that is greater than the first RF power, wherein all of the plurality of ALD layers is densified (step 112). FIG. 7 is a more detailed flow chart of the step of densifying the plurality of ALD layers (step 112). A densifying gas is flowed into the processing chamber (step 704). In this example, the densifying gas comprises one or more of H₂, N₂, Ar, N₂O, O₂, and He. The densifying gas is transformed into a plasma (step 708). In this example, the second RF is provided is in the range of 2500 to 5500 watts applied through the gas distribution plate 206. A bias RF power in the range of 2500 to 5500 watts may also be applied through the ESC 208. After 0.1 to 1 seconds the flow of the densifying gas is stopped (step 712). In this example, the RF power for densifying is about equal to the RF power for providing the optimized silicon oxide deposition. Such an optimized silicon oxide deposition provides a RF power that energizes the plasma to reach all of the plurality of layers, so that all of the plurality of layers is densified without damaging the intermediate layer 508. The densification transforms the ALD layers to high quality ALD layers 512, without damaging the intermediate layer 508.

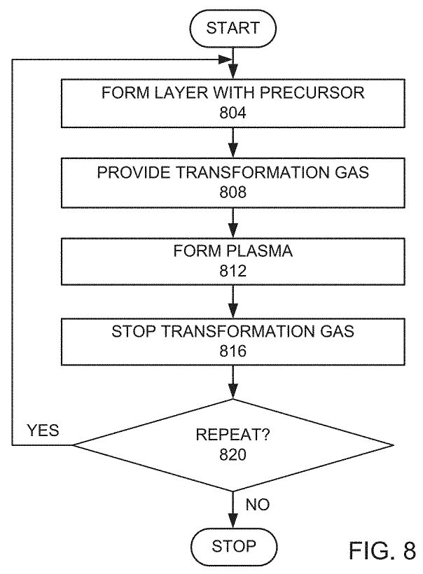

A plurality of plasma ALD layers is deposited with a third RF power that is higher than the first RF power (step 116) to deposit regular ALD silicon oxide layers. FIG. 8 is a more detailed flow chart of providing the plurality of plasma ALD layers with a third RF power that is higher than the first RF power (step 116). In this example, for depositing silicon oxide, a silicon containing precursor of a silane is provided, such as bis(diethylamino)silane (BDEAS), bis(tert-butylamino)silane (BTBAS), diisopropylamino silane (DIPAS), tris(dimethylamino)silane (TDMAS) or other silanes (step 804). In this example, the silane forms a monolayer on a surface of previously deposited ALD layers. In this example, the flow of the silicon containing precursor into the plasma processing chamber is stopped and a transformation gas is provided by flowing the transformation gas into the plasma processing chamber (step 808). In this example, the transformation gas comprises N₂O, He, O₂, and Ar. The transformation gas is transformed into a plasma (step 812). In this example, the third RF power is used to transform the transformation gas into a plasma. In this example, the third RF power provided is in the range of 2500 to 5500 watts applied through the gas distribution plate 206. A bias RF power in the range of 2500 to 5500 watts may also be applied through the ESC 208. The plasma from the transformation gas reacts with the silicon containing precursor layer to transform the precursor layer into silicon oxide. The flow of the transformation gas is stopped (step 816). The cycle is repeated (step 820) until a silicon oxide deposition reaches a desired thickness. FIG. 5C is a cross sectional view of part of the stack after the plurality of plasma ALD layers 516 has been deposited using a third RF power. Because the deposition process has a third RF power that is higher than the first RF power a high quality silicon oxide layer is deposited. Since the ALD layers deposited at the third RF power 516 are deposited over the ALD layers deposited with the first RF power 512, the ALD layers deposited with the first RF power 512 prevent damage to the intermediate layer 508.

If the densifying RF is too low, then some of the ALD layers will not be densified, resulting in lower quality ALD layers, which may increase device defects. If the densifying RF is too high, then the intermediate layer will be damaged, which may increase device defects. The densifying RF is set at a required level in order to provide a high quality silicon oxide deposition. Therefore ALD layers using the first RF power must be deposited to a certain thickness before the densifying is provided. If the thickness is too low, then the intermediate layer 508 would be damaged. If the thickness is too high, then not all of the layers will be densified. As a result, embodiments measure the depth of penetration caused by a plasma with the second RF power and then provides a plurality of ALD layers using the first RF power at a thickness equal to the depth of penetration.

In an embodiment, the determination of depth penetration includes a series thickness and leakage studies. First, an ALD film is deposited with the third RF power that is higher than the first RF power on a bare Si substrate and a measurement is done for leakage and thickness. Then an ALD film is deposited with the first RF power that is lower than the regular RF power for 5, 10, 20, and 30 cycles followed by densifying the ALD film followed by thickness and leakage measurements. If the plasma penetration is more than the soft layer, then the thickness would be higher compared to desired plasma penetration depth due to silicon oxide formation at the substrate. If the plasma penetration is not enough then some of the soft layers will not be densified during the densification treatment and the resulting thickness and leakage will be higher compared to desired plasma penetration depth. Therefore, plasma penetration depth exists as a minima if we plot thickness vs. soft ALD cycle number. FIG. 9 is a bar graph of regular ALD, 10 cycles of soft ALD, 20 cycles of soft ALD, and 30 cycles of soft ALD, versus thickness of silicon oxide in angstroms. In this example, the regular ALD silicon oxide deposition provides the thickest silicon oxide layer. The 10 cycles of soft ALD silicon oxide deposition deposits the thinnest silicon oxide layer. The 20 cycles of soft ALD silicon oxide deposition deposits the next thinnest silicon oxide layer. The 30 cycles of soft ALD silicon oxide deposition deposits the next thinnest silicon oxide layer. From this graph it is determined that the plasma penetration is about 10 layers of soft ALD silicon oxide deposition, since the increase of silicon oxide thickness with additional cycles is attributed to soft ALD silicon oxide deposition layer that are not densified by the densification process, because of insufficient plasma penetration.

In some embodiments, the second RF power provided during densification is at least three times the first RF power provided for depositing the lower power plasma ALD layers. More preferably, the second RF power provided during densification is at least five times the first RF power provided for depositing the lower power plasma ALD layers. In some embodiments, the third RF power is at least three times the first RF power. More preferably, the third RF power is at least five times the first RF power. In various embodiments, the first RF power is between about 500 to 1000 Watts. In various embodiments, the second RF power and the third RF power are more than 500 Watts greater than the first RF power.

In various embodiments, the intermediate layer has a threshold RF budget before the intermediate layer has significant damage. RF exposure would be measured by the RF power times the time the intermediate layer is exposed to the RF power. By providing a low RF power to form the plurality of plasma ALD layers deposited with a first RF power, the intermediate layer has a RF exposure below the threshold RF budget. Although the densifying uses a higher RF power, since the plasma generated during the densifying is prevented from reaching the intermediate layer by the plurality of plasma ALD layers, the densifying does not cause the RF exposure to exceed the RF budget. Therefore, the densifying may be performed with a RF power more than five times the RF power used during the formation of the ALD layers at the first RF and may also provide RF for a longer period. In some embodiment, the RF exposure during the providing the first RF power to form the plurality of plasma ALD layers is optimized to be about equal to the RF budget.

In various embodiments a wet etch rate ratio may be used to indicate if the plurality of ALD layers are formed using a lower RF resulting in a lower quality and lower density deposition or if the plurality of ALD layers are formed using a higher RF resulting in high quality and higher deposition. A high quality ALD layer deposition has a wet etch rate of less than 5. The lower quality ALD deposition has a higher wet tech rate. However, after densification, the densified ALD densification has a wet etch rate of less than 5.

In various embodiments, the densifying gas may be a gas comprising an inert gas such as helium (He) or argon (Ar). In an embodiment, the densifying gas may consist essentially of oxygen (O₂) and He. In another embodiment, the densifying gas may consist essentially of O₂ and Ar. In other embodiment, the densifying gas may consist essentially of O₂, He, and Ar.

Damage is considered to be any changed at the interface layer where the film is being deposited. Damage could be the oxidation of under layer, sputtering of the underlayer, or chemical etch of the underlayer.

While this disclosure has been described in terms of several preferred embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure.

What is claimed is:

1. A method for depositing a layer on a substrate, comprising:
depositing a plurality of plasma atomic layer deposition (ALD) layers over the substrate, wherein each plasma ALD layer of the plurality of ALD layers is deposited at a first RF power; and
densifying the plurality of plasma ALD layers, comprising generating a densifying plasma using a second RF power greater than the first RF power, wherein at least one of the plurality of plasma ALD layers are densified.

2. The method, as recited in claim 1, wherein the densifying the plurality of plasma ALD layers densifies all of the plurality of plasma ALD layers.

3. The method, as recited in claim 2, wherein the depositing the plurality of plasma ALD layers over the substrate deposits least five plasma ALD layers.

4. The method, as recited in claim 2, wherein the depositing a plurality of plasma ALD layers over the substrate deposits at least ten plasma ALD layers.

5. The method, as recited in claim 4, wherein ions from the densifying plasma do not reach the substrate.

6. The method, as recited in claim 2, wherein ions from the densifying plasma do not reach the substrate.

7. The method, as recited in claim 2, further comprising providing a plurality of plasma ALD layers over the densified plurality of plasma ALD layers, using a third RF which is greater than the first RF power.

8. The method, as recited in claim 7, wherein the providing a plurality of plasma ALD layers over the densified plurality of plasma ALD layers, using a third RF power which is greater than the first RF power, comprises:
flowing a precursor to form a layer of precursor;
stopping the flow of the precursor;
providing a transformation gas;
providing RF power at the third RF power to form the transformation gas into a plasma, which transforms the layer of precursor; and
stopping the flow of the transformation gas.

9. The method, as recited in claim 2, wherein the first RF power is between about 500 to 1000 Watts.

10. The method, as recited in claim 2, wherein depositing the plurality of ALD layers deposits the plurality of ALD layers to a thickness of about 10 to 50 Å thick.

11. The method, as recited in claim 2, wherein the depositing a plurality of plasma ALD layers over the substrate deposits a plurality of silicon oxide layers.

12. The method, as recited in claim 2, wherein the depositing the plurality of plasma ALD layers over the substrate, comprises a plurality of cycles, wherein each cycle comprises:
flowing a precursor to form a layer of precursor;
stopping the flow of the precursor;
providing a transformation gas;
providing an RF power at the first RF power to form the transformation gas into a plasma, which transforms the layer of precursor; and
stopping the flow of the transformation gas.

13. The method, as recited in claim 12, wherein the plurality of cycles are repeated at least five times.

14. The method, as recited in claim 12, wherein the precursor gas is a silane containing gas.

15. The method, as recited in claim 2, wherein the second RF power is at least five times the first RF power.

16. The method, as recited in claim 2, further comprising determining a plasma penetration depth at the second RF power.

17. The method, as recited in claim 16, wherein the transformation gas comprises at least one of N₂O, He, O₂, or Ar.

18. The method, as recited in claim 2, wherein the densifying the plurality of plasma ALD layers, comprises:
providing a densifying gas; and
forming a plasma from the densifying gas, by providing RF power at the second RF power.

19. The method, as recited in claim 18, wherein the densifying gas comprises at least one of H₂, N₂, Ar, N₂O, O₂, or He.
